(19) United States
(12) Patent Application Publication
(10) Pub. No.: US 2025/0349571 A1
(43) Pub. Date: Nov. 13, 2025

(54) BEVEL SEALING SYSTEM AND METHOD OF USING THE SAME

(71) Applicant: Taiwan Semiconductor Manufacturing Co., Ltd., Hsinchu (TW)

(72) Inventors: Yu-Meng Ou, Taoyuan City (TW); Kei-Wei Chen, New Taipei City (TW)

(21) Appl. No.: 19/276,316

(22) Filed: Jul. 22, 2025

Related U.S. Application Data
(63) Continuation of application No. 18/619,605, filed on Mar. 28, 2024.
(60) Provisional application No. 63/582,941, filed on Sep. 15, 2023.

(51) Int. Cl. H01L 21/67; H01L 21/687

(52) U.S. Cl. CPC H01L 21/67126; H01L 21/67092; H01L 21/67242; H01L 21/68735

(57) ABSTRACT

In an embodiment, a bevel sealing system includes a dispensing chamber that includes a first chuck configured to support a workpiece, the workpiece including a first wafer bonded to a second wafer, where the first wafer and the second wafer include beveled edges, a sealant dispenser configured to apply sealant along a perimeter of a bonding interface between the first wafer and the second wafer, a first Charge-Coupled Device (CCD) camera configured to capture 2-dimensional (2D) images of edges of the workpiece, and a first laser edge profiler configured to measure and collect profile data of the edges of the workpiece.

### CROSS-REFERENCE TO RELATED APPLICATIONS

This application is a continuation of U.S. application Ser. No. 18/619,605, Mar. 28, 2024, which claims priority to U.S. Application No. 63/582,941, filed on Sep. 15, 2023, which applications are hereby incorporated herein by reference.

### BACKGROUND

In wafer-to-wafer bonding technology, various methods have been developed to bond two wafers together. The available bonding methods include fusion bonding, eutectic bonding, direct metal bonding, hybrid bonding, and the like. After the bonding of the two wafers, an epoxy sealant may be dispensed along the perimeter of the bonded wafers. Specifically, the epoxy sealant is dispensed at the interface of the bonded wafers in order to form a bevel seal. The bevel seal ensures that the bonded interface between the two wafers is protected from environmental factors that could degrade the integrity of the bond or affect the performance of the semiconductor devices on the wafers. The bevel seal creates a barrier that prevents the penetration of moisture, particles, or other contaminants into the bonded region. There is a continuous need to modify the method for forming the bevel seal in order to improve the reliability of semiconductor devices being manufactured, as well as reducing manufacturing costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top-view of a bevel sealing system, in accordance with some embodiments.

FIGS. 2 through 4 illustrate cross-sectional views of intermediate stages in the manufacturing of a semiconductor device, in accordance with some embodiments.

FIG. 5 schematically illustrates a first process flow used to form a bevel seal along a perimeter of a bonding interface between a first wafer and a second wafer, in accordance with some embodiments.

FIG. 6 schematically illustrates a second process flow used to perform a cleaning process on beveled edges of a first wafer and a second wafer, in accordance with some embodiments.

FIG. 7A illustrates a first inspection process of an edge of a workpiece during an intermediate stage in the manufacturing of a semiconductor device, in accordance with some embodiments.

FIG. 7B illustrates an example 2D image of the edge of the workpiece described in FIG. 7A, in accordance with some embodiments.

FIG. 7C illustrates a reconstructed 3D representation of a cross-section of the edge of the workpiece described in FIG. 7A, in accordance with some embodiments.

FIGS. 8A and 8B illustrate a sealant dispensing process during an intermediate stage in the manufacturing of a semiconductor device, in accordance with some embodiments.

FIG. 9A illustrates a second inspection process of an edge of a workpiece during an intermediate stage in the manufacturing of a semiconductor device, in accordance with some embodiments.

FIG. 9B illustrates an example 2D image of the edge of the workpiece described in FIG. 9A, in accordance with some embodiments.

FIG. 9C illustrates a reconstructed 3D representation of a cross-section of the edge of the workpiece described in FIG. 9A, in accordance with some embodiments.

FIG. 10 illustrates a cleaning process performed on an edge of a workpiece, in accordance with some embodiments.

FIG. 11A illustrates an example 2D image of an edge of a workpiece captured during an inspection process, in accordance with some embodiments.

FIG. 11B illustrates a reconstructed 3D representation of a cross-section of the edge of the workpiece described in FIG. 11A, in accordance with some embodiments.

FIGS. 12 through 16 illustrate cross-sectional views of intermediate stages in the manufacturing of a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A bevel sealing system is provided in accordance with various exemplary embodiments. A first wafer and a second wafer may be bonded together using a suitable method such as fusion bonding, direct metal bonding, hybrid bonding, or the like to form a workpiece. A bevel sealing process may be performed using the bevel sealing system in order to form a bevel seal along a perimeter of the bonding interface between the first wafer and the second wafer. The bevel seal is formed by dispensing a sealant in a first space between a beveled edge of the first wafer and a beveled edge of the second wafer. The first space extends around the perimeter of the bonding interface between the first wafer and the second wafer. The bevel sealing system comprises a laser edge profiler and a Charge-Coupled Device (CCD) camera, which are used to perform a first inspection of the perimeter of the workpiece, including the beveled edges of the bonded first wafer and the second wafer, as well as the bonding interface between the first wafer and the second wafer. The first inspection is performed prior to performing the bevel sealing process, and the first inspection allows the bevel sealing system to determine an optimal dispensing path and height along the perimeter of the workpiece in which to apply the sealant. In addition, the first inspection can be used to determine the volume of sealant that is needed to be dispensed in order to adequately fill the first space between the beveled edge of the first wafer and the beveled edge of the second wafer. A second inspection using the laser edge profiler and the CCD camera is performed after the bevel sealing process to determine the quality of the bevel seal formed. The second inspection can determine if an adequate volume of sealant needed to fill the first space has been dispensed, or if portions of the sealant have splashed out of the first space and onto other surfaces of the beveled edges of the first wafer and/or the second wafer. Therefore, the second inspection can determine if a cleaning process needs to be performed to clean the splashed sealant from the surfaces of the beveled edges of the first wafer and/or the second wafer. It can also determine if a further re-work process needs to be performed to dispense more sealant in the first space if the volume of the sealant is inadequate. As a result, a high quality bevel seal can be formed that allows for improved device reliability and reduced manufacturing costs. In addition, the resulting bevel seal that is formed is highly resistant to subsequent thinning operations that are used to remove or reduce a thickness of the first wafer or the second wafer. As a result, the edges of the workpiece are strengthened due to the formation of the high quality bevel seal, which allows for a reduced amount of peeling of the materials of the first wafer and the second wafer at the edges of the bonding interface during the thinning operations. Further, the use of the first inspection and/or the second inspection allows for detection of defects (e.g., edge defects on the first wafer and/or the second wafer) and bonding misalignments between the first wafer and the second wafer.

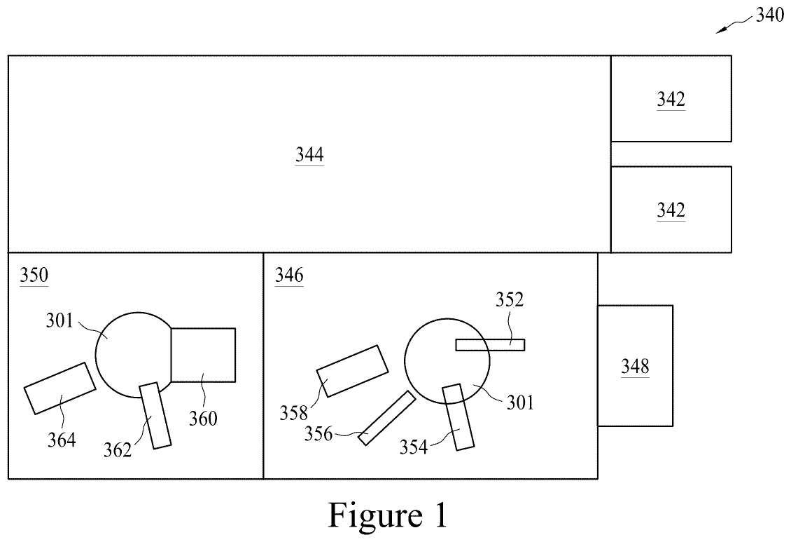

FIG. 1 shows a top-view of a bevel sealing system 340 that is used to form a bevel seal 225 (shown subsequently in FIG. 4) along a perimeter of the bonding interface between a first wafer 10 and a second wafer 20 of a workpiece 301 (also shown subsequently in FIG. 3). The first wafer 10 is bonded to the second wafer to form the workpiece 301. The bevel sealing system 340 may comprise one or more load ports 342 through which the workpiece 301 may be loaded into the bevel sealing system 340. The bevel sealing system 340 may be located in a controlled environment filled with, for example, clean air or nitrogen. Alternatively, the bevel sealing system 340 is located in open air. The bevel sealing system 340 may comprise a wafer transfer station 344, where the workpiece 301 can be staged before being transferred to different chambers of the bevel sealing system 340 where different processes can be performed on the workpiece 301. A transfer robot is used to transfer the workpiece 301 between the wafer transfer station 344 and the other chambers (also referred to as stations) of the bevel sealing system 340. The bevel sealing system 340 comprises a dispensing chamber 346, in which the bevel seal 225 (shown subsequently in FIG. 4) is formed along the perimeter of the bonding interface between the first wafer 10 and the second wafer 20 of the workpiece 301.

The dispensing chamber 346 comprises an aligner 352, a laser edge profiler 354, a dispenser 356, and a Charge-Coupled Device (CCD) camera 358. The dispensing chamber 346 may also comprise a chuck, or the like, that is used to support the workpiece 301 while it is in the dispensing chamber 346. A vacuum system may be used to secure the workpiece 301 to the chuck, ensuring it remains in place during processing. In an embodiment, the chuck may also be rotatable. The aligner 352 is used to align the workpiece 301 to a desired angular position. This alignment ensures that subsequent processing steps, such as a bevel sealing process (shown subsequently in FIG. 4), or the like, are performed accurately. The laser edge profiler 354 (which also may be referred to subsequently as the surface profiler) and the CCD camera 358 are used in combination to perform a first inspection of the edges of the workpiece 301, prior to performing the bevel sealing process. For example, the CCD camera 358 captures 2-dimensional (2D) images along the perimeter of the workpiece 301, including beveled edges of the first wafer 10 and the second wafer 20. The laser edge profiler 354 collects data by measuring the profile (e.g. the shape) of the beveled edges of the first wafer 10 and the second wafer 20, in addition to measuring the profile of a first space 223 (shown subsequently in FIG. 3) between a beveled edge of the first wafer 10 and a beveled edge of the second wafer 20. The first space 223 extends around the perimeter of the bonding interface between the first wafer 10 and the second wafer 20. This data is measured at various points along the perimeter of the workpiece 301. The 2D images collected by the CCD camera 358 and the data measured by the laser edge profiler 354 are sent to a data processor 348 which applies various algorithms to process the data, and reconstructs a 3-dimensional (3D) representation of the edges of the workpiece 301. The data processor 348 also uses the 2D images collected by the CCD camera 358 and the reconstructed 3D representation of the edges of the workpiece 301 to determine an optimal dispensing path and height along the perimeter of the workpiece 301 in which to apply a sealant (shown subsequently in FIG. 4) during the bevel sealing process to form the bevel seal 225. In addition, the data processor 348 uses the 2D images collected by the CCD camera 358 and the reconstructed 3D representation of the edges of the workpiece 301 to determine the volume of sealant that is needed to be dispensed in order to adequately fill the first space 223 between the beveled edge of the first wafer 10 and the beveled edge of the second wafer 20. The laser edge profiler 354 and the CCD camera 358 can be used in combination to perform a second inspection after the bevel sealing process is performed (e.g., after forming the bevel seal 225), in order to determine the quality of the bevel seal 225 that is formed. The dispenser 356 is used to apply small amounts of sealant to specific locations or surfaces along the perimeter of the bonding interface between the first wafer 10 and the second wafer 20 during the bevel sealing process, in order to adequately fill the first space 223 and form the bevel seal 225.

The bevel sealing system 340 also comprises a cleaning chamber 350. The cleaning chamber 350 comprises cleaning apparatus 360, a laser edge profiler 362, and a Charge-Coupled Device (CCD) camera 364. The cleaning chamber 350 may also comprise a chuck, or the like, that is used to support the workpiece 301 while it is in the cleaning chamber 350. A vacuum system may be used to secure the workpiece 301 to the chuck, ensuring it remains in place during processing. In an embodiment, the chuck may also be rotatable. The cleaning apparatus 360 is used to perform a cleaning process on the workpiece 301 if it is found during the second inspection that any of the sealant used to form the bevel seal 225 (shown subsequently in FIG. 4) during the bevel sealing process has splashed out of the first space 223 and onto other surfaces (e.g., beveled edges of the first wafer 10 and/or the second wafer 20, a top surface of the second wafer 20, and a bottom surface of the first wafer 10). The cleaning apparatus 360 may comprise on one or more cleaning brushes (e.g., a top/bottom cleaning brush and a side cleaning brush) that are rotatable and that may be brought into contact with edges and/or a top/bottom surface of the workpiece 301. For example, the cleaning brushes may comprise one or more side cleaning brushes that are rotatable and that can be brought into contact with beveled edges of the first wafer 10 and the second wafer 20 to remove and wipe out the splashed sealant on the beveled edges of the first wafer 10 and the second wafer 20. The cleaning brushes may comprise one or more top/bottom cleaning brushes that are rotatable and that can be brought into contact with a top surface of the second wafer 20 and/or a bottom surface of the first wafer 10 to remove and wipe out the splashed sealant on the bottom surface of the first wafer 10 and/or the top surface of the second wafer 20.

The laser edge profiler 362 and the CCD camera 364 may be similar to the laser edge profiler 354 and the CCD camera 358, respectively, which were described above. The laser edge profiler 362 (which also may be referred to subsequently as the surface profiler) and the CCD camera 364 may be used to perform a third inspection after the cleaning process on the workpiece 301 is performed. The third inspection is used to determine if the cleaning process on the workpiece 301 has successfully removed the splashed sealant from the beveled edges of the first wafer 10 and the second wafer 20, and from the top surface of the second wafer 20 and/or the bottom surface of the first wafer 10. The third inspection will therefore determine if a further cleaning process is still needed. The third inspection can also be used to determine if after the cleaning process on the workpiece 301, the volume of the sealant in the first space 223 between the beveled edge of the first wafer 10 and the beveled edge of the second wafer 20 is inadequate, and if a further re-work process needs to be performed in the dispensing chamber 346 to dispense more sealant in the first space 223.

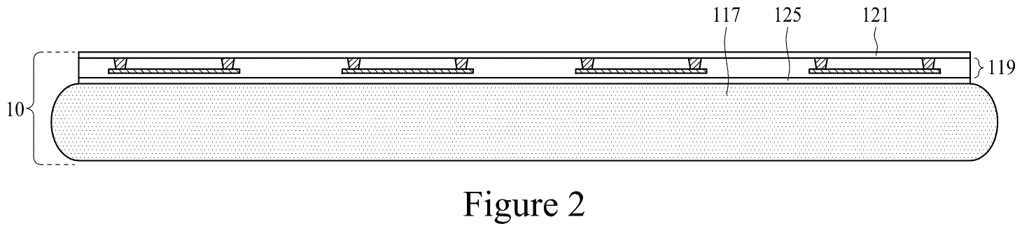

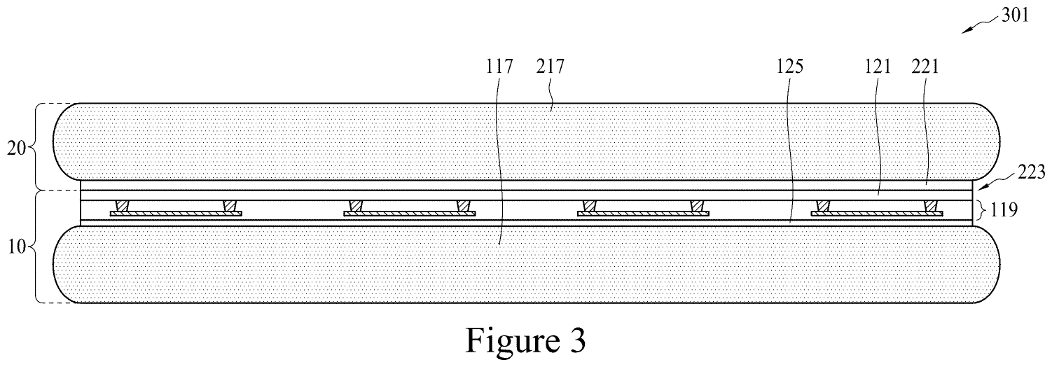

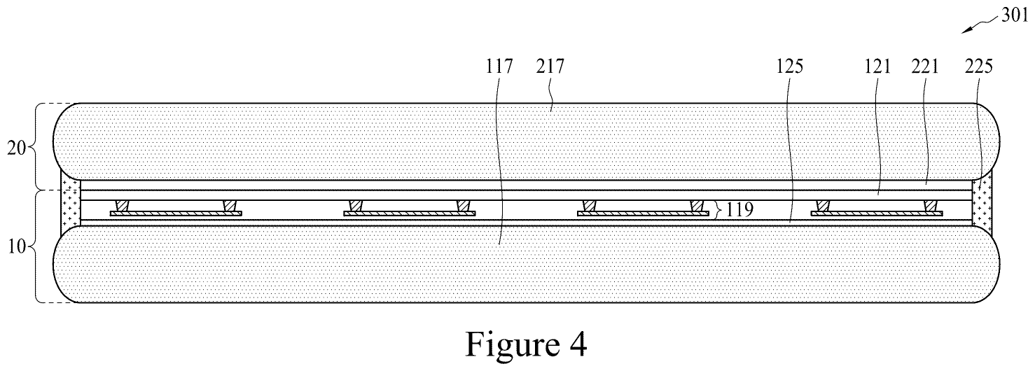

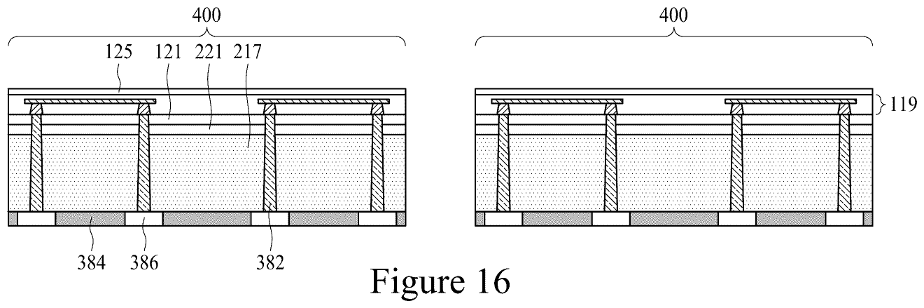

FIGS. 2 through 4 are cross-sectional views of intermediate stages in the manufacturing of a semiconductor device 400, in accordance with some embodiments. FIG. 5 schematically illustrates a process flow 300 used to form the bevel seal 225 (shown subsequently in FIG. 4) along a perimeter of a bonding interface between a first wafer 10 and a second wafer 20. FIG. 6 schematically illustrates a process flow 320 that is used to perform a cleaning process on beveled edges of the first wafer 10 and the second wafer 20. FIGS. 12 through 16 are cross-sectional views of intermediate stages in the manufacturing of a semiconductor device 400, in accordance with some embodiments.

FIG. 2 illustrates the first wafer 10. The first wafer 10 may also be referred to subsequently as a device wafer. The first wafer 10 may comprise a die, and may include a substrate 117 (e.g., a semiconductor substrate), an interconnect structure 119 disposed on the substrate 117, and a bonding layer 121 disposed on the interconnect structure 119, the bonding layer 121 being exposed at the front surface of the first wafer 10. The side of the first wafer 10 comprising the bonding layer 121 may also be referred to subsequently as the front side of the first wafer 10, and the side of the first wafer 10 comprising the exposed surface of the substrate 117 may be referred to subsequently as the back side of the first wafer 10.

The substrate 117 of the first wafer 10 may include a crystalline silicon wafer. The substrate 117 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be for n-type Fin-type Field Effect Transistors (FinFETs) and/or p-type FinFETs. In some alternative embodiments, the substrate 117 may comprise an active layer of a semiconductor-on-insulator (SOI) substrate. The substrate 117 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The edges of the substrate 117 include bevels which are surfaces that extend from the outermost edges of the substrate 117 to the top/bottom surfaces of the substrate 117. The bevels may be rounded bevels (as shown in FIG. 2) having curved surfaces that extend from the outermost edges of the substrate 117 to the top/bottom surfaces of the substrate 117. In other embodiments, the bevels may have a slope (not shown in the Figures) that extends from the outermost sidewall of the substrate 117 to the top/bottom surfaces of the substrate 117.

Active and/or passive devices, such as transistors, diodes, capacitors, resistors, etc., may be formed in and/or on the substrate 117 to form a device layer 125. The devices of the device layer 125 may be interconnected by the interconnect structure 119. The interconnect structure 119 electrically connects the devices on the substrate 117 to form one or more integrated circuits. The interconnect structure 119 may include one or more dielectric layers (for example, one or more interlayer dielectric (ILD) layers, intermetal dielectric (IMD) layers, or the like) and interconnect wirings or metallization patterns embedded in the one or more dielectric layers. The material of the one or more dielectric layers may include silicon oxide, silicon nitride, silicon oxynitride, or another suitable dielectric material. The interconnect wirings may include metallic wirings. For example, the interconnect wirings include copper wirings, copper pads, aluminum pads or combinations thereof that are formed by one or more single damascene processes, dual damascene processes, or the like.

The bonding layer 121 may comprise a dielectric layer. The material of the bonding layer 121 may be silicon oxide, silicon nitride, silicon oxynitride, tetraethyl orthosilicate (TEOS), or other suitable dielectric material. The bonding layer 121 may be formed by depositing a dielectric material over the interconnect structure 119 using a chemical vapor deposition (CVD) process (e.g., a plasma enhanced CVD process or other suitable process), or the like.

As illustrated in FIG. 2, the interconnect structure 119 and the bonding layer 121 do not overlap the beveled edges of the substrate 117. For example, outer portions (e.g. the beveled edges) of the substrate 117 extend laterally beyond respective outermost sidewalls of the interconnect structure 119 and the bonding layer 121.

In FIG. 3, a second wafer 20 is bonded to the front side of the first wafer 10 to form the workpiece 301. The workpiece 301 may also be referred to subsequently as a wafer stack. The second wafer 20 may also be referred to subsequently as a carrier wafer. The second wafer 20 may comprise a semiconductor substrate 217, which may include a crystalline silicon wafer, a silicon based carrier substrate (e.g., comprising silicon oxide), or the like. The edges of the semiconductor substrate 217 include bevels which are surfaces that extend from the outermost edges of the semiconductor substrate 217 to the top/bottom surfaces of the semiconductor substrate 217. The bevels may be rounded bevels (as shown in FIG. 3) having curved surfaces that extend from the outermost edges of the semiconductor substrate 217 to the top/bottom surfaces of the semiconductor substrate 217. In other embodiments, the bevels may have a slope (not shown in the Figures) that extends from the outermost sidewall of the semiconductor substrate 217 to the top/bottom surfaces of the semiconductor substrate 217. A bonding layer 221 is disposed over the semiconductor substrate 217. In some embodiments, the bonding layer 221 may comprise silicon oxide that is formed by a deposition process, such as chemical vapor deposition (CVD), physical vapor deposition (PVD), or the like. In other embodiments, the bonding layer 221 may be formed by the thermal oxidation of a silicon surface on the semiconductor substrate 217. As illustrated in FIG. 3, the bonding layer 221 does not overlap the beveled edges of the semiconductor substrate 217. For example, outer portions (e.g. the beveled edges) of the semiconductor substrate 217 extend laterally beyond respective outermost sidewalls of the bonding layer 221.

The first wafer 10 is bonded to the second wafer 20, such that the bonding layer 121 of the first wafer 10 is attached to the bonding layer 221 of the second wafer 20 using a suitable technique such as dielectric-to-dielectric bonding, or the like. Prior to bonding, at least one of the bonding layers 121 or 221 may be subjected to a surface treatment. The surface treatment may include a plasma treatment. The plasma treatment may be performed in a vacuum environment. After the plasma treatment, the surface treatment may further include a cleaning process (e.g., a rinse with deionized water, or the like) that may be applied to the bonding layers 121 and/or bonding layer 221. The second wafer 20 is then aligned and then placed by, e.g., a pick-and-place process. The first wafer 10 and the second wafer 20 are pressed against each other to initiate a pre-bonding of the first wafer 10 to the second wafer 20. The pre-bonding may be performed at room temperature (between about 20 degrees and about 25 degrees). The bonding time may be shorter than about 1 minute, for example. After the pre-bonding, the first wafer 10 and the second wafer 20 are bonded to each other. The bonding process may be strengthened by a subsequent annealing step. For example, this may be done by heating the first wafer 10 and the second wafer 20 to a temperature of about 300 degrees for about 3 hours.

Since the outer portions (e.g. the beveled edges) of the substrate 117 extend laterally beyond the respective outermost sidewalls of the interconnect structure 119 and the bonding layer 121, and the outer portions (e.g. the beveled edges) of the semiconductor substrate 217 extend laterally beyond the respective outermost sidewalls of the bonding layer 221, after the bonding of the bonding layer 121 to the bonding layer 221, a first space 223 is formed between a lower beveled edge of the second wafer 20 and an upper beveled edge of the first wafer 10. In some embodiments, the first space 223 may include a lateral void that extends partially into each of the bonding layer 121 and the bonding layer 221. The first space 223 extends along the perimeter of bonding interface between the first wafer 10 and the second wafer 20.

In FIG. 4, the bevel seal 225 is formed in the first space 223 between the lower beveled edge of the second wafer 20 and the upper beveled edge of the first wafer 10. The bevel seal 225 is formed using the bevel sealing system 340 (described previously in FIG. 1). The bevel seal 225 is formed along the perimeter of the bonding interface between the first wafer 10 and the second wafer 20 of the workpiece 301.

FIG. 5 schematically illustrates a process flow 300 and the bevel sealing system 340 for performing the process flow 300. The bevel sealing system 340 and the process flow 300 is used to form the bevel seal 225 (shown previously in FIG. 4) that is formed in the first space 223. The details of the process flow 300 and the bevel sealing system 340 are discussed below, referencing FIGS. 1, 5, and 7A through 9C.

In step 302 of the process flow 300 (shown in FIG. 5), the workpiece 301 is delivered to one of the load ports 342 of the bevel sealing system 340. In step 304 of the process flow 300 (shown in FIG. 5), a transfer robot is then used to transfer the workpiece 301 from the load port 342 to the wafer transfer station 344, where the workpiece 301 can be staged for transfer to any other chamber of the bevel sealing system 340. In step 306 of the process flow 300 (shown in FIG. 5), the transfer robot then transfers the workpiece 301 from the wafer transfer station 344 to the dispensing chamber 346, where an alignment process of the workpiece 301 is performed by the aligner 352. The aligner 352 aligns the workpiece 301 to a desired angular position. This alignment ensures that subsequent processing steps of the process flow 300 are performed accurately.

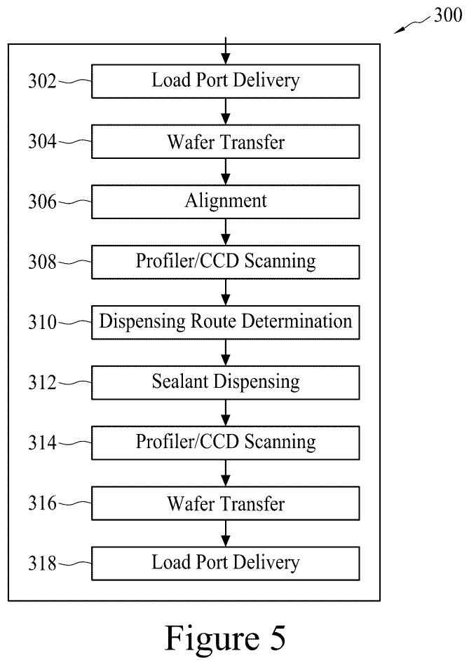

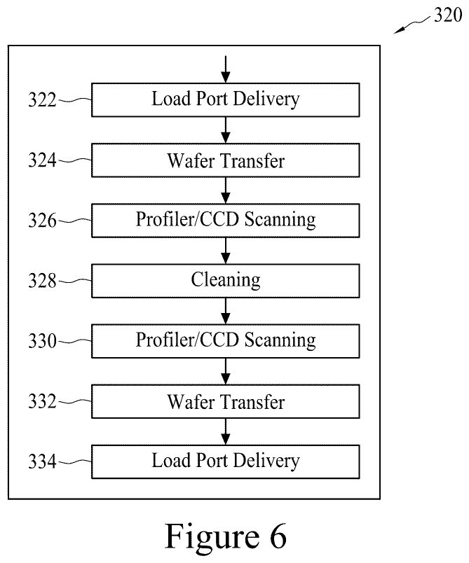

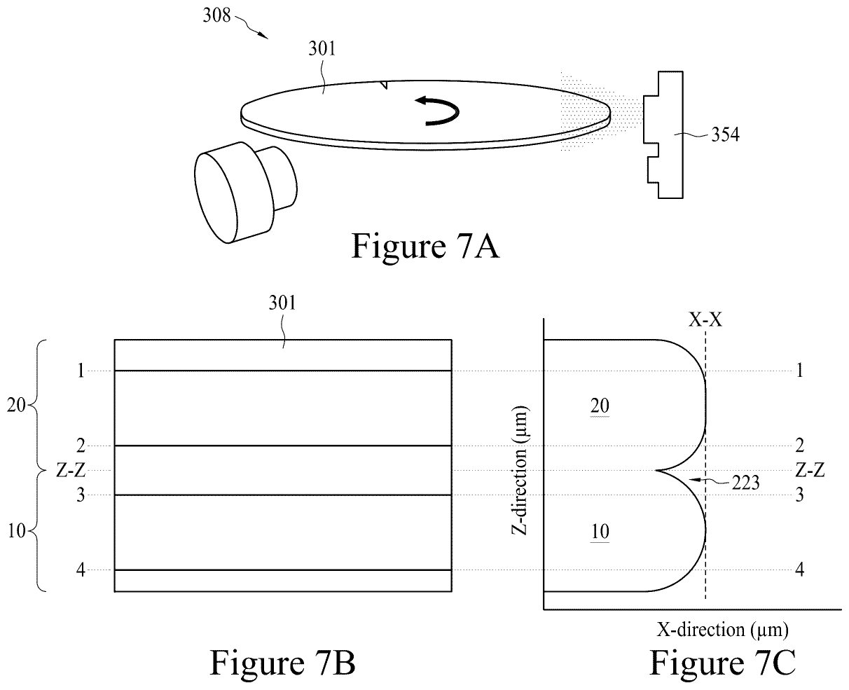

After the step 306 of the process flow 300 is performed, a step 308 of the process flow 300 (shown in FIG. 5) is performed. In the step 308 of the process flow 300, a first inspection of the edges of the workpiece 301 is performed in the dispensing chamber 346 using a combination of the laser edge profiler 354 and the CCD camera 358. Referring to FIGS. 1 and 7A, each of the CCD camera 358 and the laser edge profiler 354 may be disposed to be adjacent to an edge of the workpiece 301. The CCD camera 358 is used to capture 2-dimensional (2D) images along the perimeter (e.g., edges) of the workpiece 301, including beveled edges of the first wafer 10 and the second wafer 20. The 2D images are captured by the CCD camera 358 as the workpiece 301 is rotated. The 2D images comprise variations in the intensity or brightness levels of objects or features within each 2D image, and these variations are typically represented in shades of gray. Grey-level contrast differences can be used to distinguish and analyze objects, patterns, or details in each 2D image, such as the positions of the beveled edges of the first wafer 10 and the second wafer 20. For example, FIG. 7B shows an example 2D image of the beveled edges of the first wafer 10 and the second wafer 20 that may be captured by the CCD camera 358. The CCD camera 358 observes the first wafer 10 and the second wafer 20 by detecting and capturing changes in light intensity at certain locations on each of the first wafer 10 and the second wafer 20. For example, horizontal lines in FIG. 7B represent a location 1 and a location 2 on the beveled edge of the second wafer 20 which are observable by the CCD camera 358 due to variations in light intensity at the location 1 and the location 2, as compared to the rest of the second wafer 20. In addition, horizontal lines in FIG. 7B represent a location 3 and a location 4 on the beveled edge of the first wafer 10 which are observable by the CCD camera 358 due to variations in light intensity at the location 3 and the location 4, as compared to the rest of the first wafer 10. In an embodiment, lighting sources can be used to illuminate the edge of the workpiece 301 to create a better contrast between the locations 1, 2, 3, and 4, and the rest of the first wafer 10 and the second wafer 20. In this way the CCD camera 358 is able to observe the positions of the first wafer 10 and the second wafer 20.

Referring further to FIGS. 1 and 7A, the laser edge profiler 354 collects data by measuring the profile (e.g. the shape and dimensions) of the beveled edges of the first wafer 10 and the second wafer 20 as the workpiece 301 is rotated. Therefore the laser edge profiler 354 collects data by measuring the profile (e.g. the shape and dimensions) of the edges of the workpiece 301. In addition, the laser edge profiler 354 measures the profile (e.g., the shape and dimensions) of the first space 223 (shown previously in FIG. 3) between the lower beveled edge of the second wafer 20 and the upper beveled edge of the first wafer 10. This data is measured at various points along the perimeter of the workpiece 301 as the workpiece 301 is rotated. The laser edge profiler 354 comprises a laser source that is used to emit laser light and illuminate the edges or surfaces being measured. The laser edge profiler 354 also comprises a detector which collects and senses the reflected (e.g., the scattered) laser light from the edges or surfaces being measured. This reflected laser light provides information about the shape, dimensions, and roughness of the measured edges or surfaces.

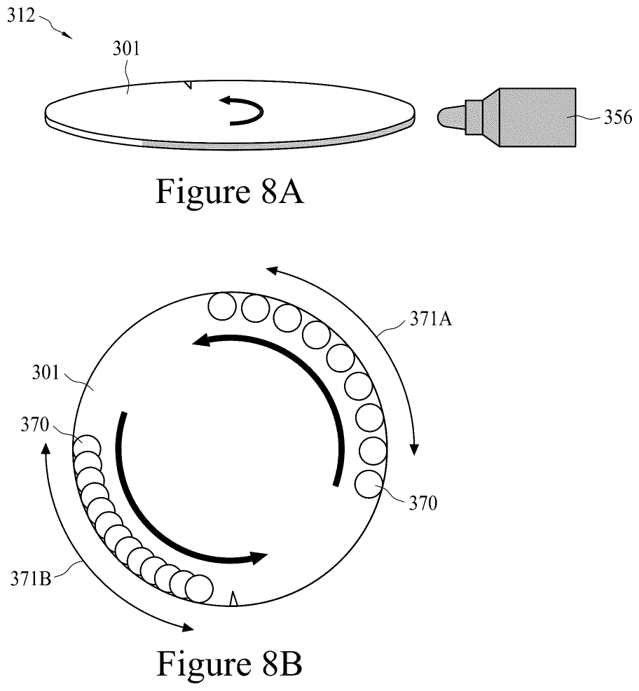

After the step 308 of the process flow 300 is performed, a step 310 of the process flow 300 (shown in FIG. 5) is performed. In step 310 of the process flow 300, the 2D images collected by the CCD camera 358 and the data measured by the laser edge profiler 354 during the first inspection are sent to the data processor 348. The data processor 348 applies various algorithms to process the data, and reconstructs a 3-dimensional (3D) representation of the edges of the workpiece 301. For example, FIG. 7C shows a reconstructed 3D representation of a cross-section of the edge of the workpiece 301 that is shown in FIG. 7B. The 3D representation of the cross-section of the edge of the workpiece 301 shows the beveled edges of the first wafer 10 and the second wafer 20, as well as the first space 223 between the lower beveled edge of the second wafer 20 and the upper beveled edge of the first wafer 10. The data processor 348 uses the 2D images collected by the CCD camera 358 and the reconstructed 3D representation of the edges of the workpiece 301 to determine an optimal dispensing path and height (e.g., shown by the horizontal line Z-Zin FIGS. 7B and 7C) along the perimeter of the workpiece 301 in which to apply a sealant (shown subsequently in FIGS. 8A and 8B) during a subsequent sealant dispensing process (e.g., the step 312 of the process flow 300). In addition, the data processor 348 uses the reconstructed 3D representation of the edges of the workpiece 301 to determine the volume of sealant that is needed to be dispensed in order to adequately fill the first space 223 between the lower beveled edge of the second wafer 20 and the upper beveled edge of the first wafer 10, which reduces a risk of overfilling the first space 223 with the sealant. As a result, a risk of the sealant splashing from out of the first space 223 and on to the beveled edges of the first wafer 10 and/or the second wafer 20 is reduced. Further, the data processor 348 can use the reconstructed 3D representation of the edges of the workpiece 301 to detect if any defects (e.g., edge defects on the beveled edges of the first wafer 10 and/or the second wafer 20) or bonding misalignments between the first wafer 10 and the second wafer 20 are present.

Advantages can be achieved by performing the first inspection in the dispensing chamber 346 using a combination of the laser edge profiler 354 and the CCD camera 358, wherein the CCD camera 358 is used to capture 2D images along the edges of the workpiece 301 as the workpiece 301 is rotated, and the laser edge profiler 354 collects data by measuring the profile (e.g. the shape and dimensions) of the edges of the workpiece 301 as the workpiece 301 is rotated. The 2D images collected by the CCD camera 358 and the data measured by the laser edge profiler 354 during the first inspection are sent to the data processor 348, which the data processor 348 uses to reconstruct a 3D representation of the edges of the workpiece 301. These advantages include the data processor 348 being able to use the 2D images collected by the CCD camera 358 and the reconstructed 3D representation of the edges of the workpiece 301 to determine an optimal dispensing path and height (e.g., shown by the horizontal line Z-Z in FIGS. 7B and 7C) along the perimeter of the workpiece 301 in which to apply a sealant during the subsequent sealant dispensing process (described in the step 312 of the process flow 300) to form the bevel seal 225. In addition, the use of the laser edge profiler 354 provides a better depth of field and a better imaging resolution than by using the CCD camera 358 by itself, allowing the laser edge profiler 354 to collect the data by measuring the profile (e.g. the shape and dimensions) of the edges of the workpiece 301. The data processor 348 uses this data to generate the reconstructed 3D representation of the edges of the workpiece 301. The data processor 348 then uses the reconstructed 3D representation of the edges of the workpiece 301 to determine the volume of sealant that is needed to be dispensed in order to adequately fill the first space 223 between the lower beveled edge of the second wafer 20 and the upper beveled edge of the first wafer 10, which reduces a risk of overfilling the first space 223 with the sealant. As a result, a risk of the sealant splashing from out of the first space 223 and on to the beveled edges of the first wafer 10 and/or the second wafer 20 is reduced. Further, the data processor 348 can use the reconstructed 3D representation of the edges of the workpiece 301 to detect if any defects (e.g., edge defects on the beveled edges of the first wafer 10 and/or the second wafer 20) or bonding misalignments between the first wafer 10 and the second wafer 20 are present.

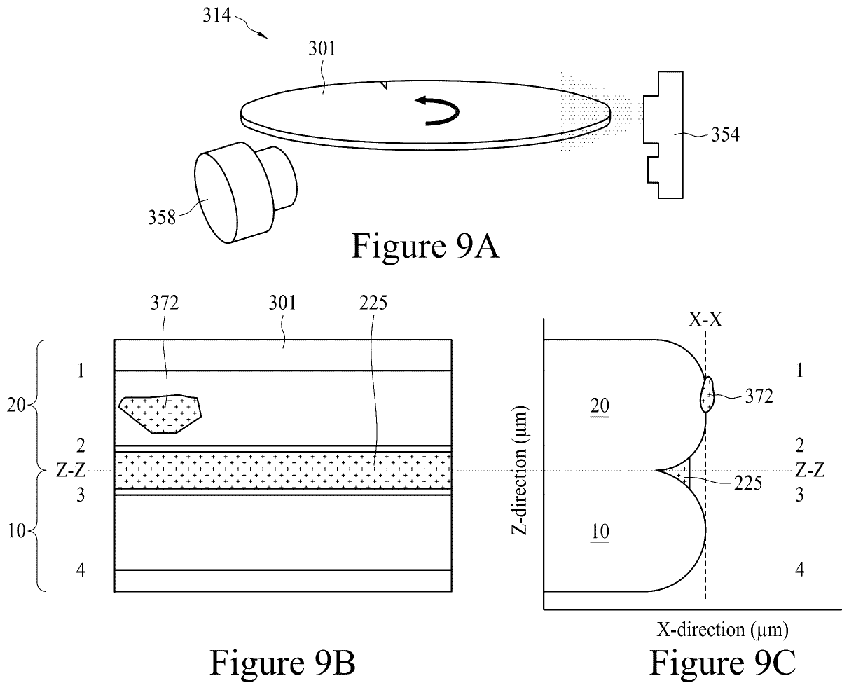

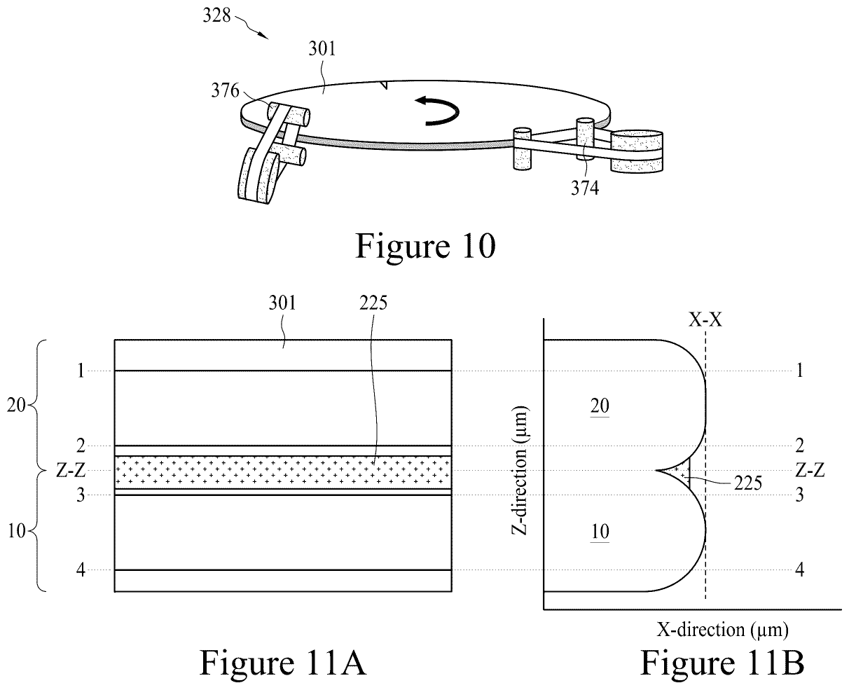

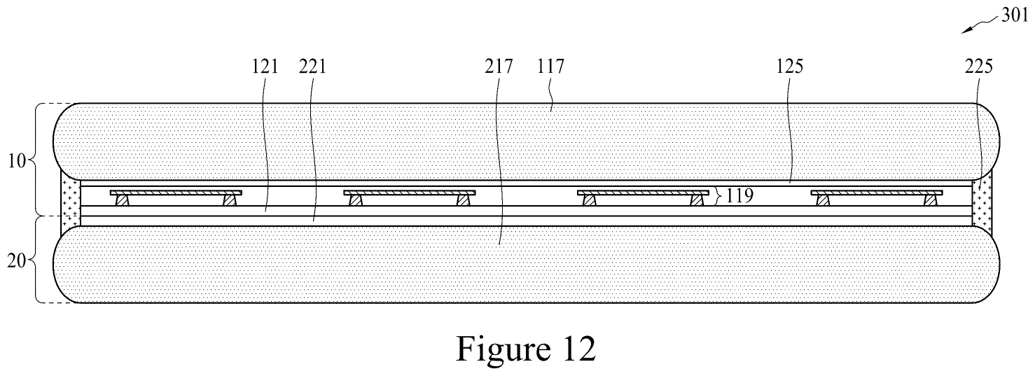

After the step 310 of the process flow 300 is performed, a step 312 of the process flow 300 (shown in FIG. 5) is performed. In the step 312 of the process flow 300, the dispenser 356 in the dispensing chamber 346 is used to dispense a sealant along the perimeter of the workpiece 301 and form the bevel seal 225 (shown subsequently in FIGS. 9B and 9C). Specifically, the sealant is dispensed along the perimeter of the bonding interface between the first wafer 10 and the second wafer 20, in order to partially or fully fill the first space 223. The sealant is dispensed as the workpiece 301 is rotated. The sealant may comprise epoxy, or the like. Referring to FIGS. 1 and 8A, the dispenser 356 may be disposed to be adjacent to an edge of the workpiece 301. The dispenser 356 may comprise a reservoir for holding the sealant, and may additionally comprise a dispensing nozzle or needle to control the flow and precision of sealant to be dispensed.

The sealant is dispensed or applied by the dispenser 356 in the form of sealant spots 370 (as shown in FIG. 8B) along the perimeter of the bonding interface between the first wafer 10 and the second wafer 20. The sealant spots 370 are dispensed in the first space 223 at the optimal dispensing path and height (e.g., the horizontal line Z-Z shown in FIGS. 7B and 7C) that was determined previously by the data processor 348 in the step 310 of the process flow 300. The sealant spots 370 combine and merge in the first space 223 around the perimeter of the bonding interface between the first wafer 10 and the second wafer 20 to form a continuous bevel seal 225 that has no gaps. In an embodiment, during the dispensing of the sealant spots 370, a speed of rotation of the workpiece 301 can be controlled so as to ensure that the volume of sealant (determined previously by data processor 348 in step 310 of the process flow 300) that is needed to be dispensed in order to adequately fill the first space 223 is dispensed into the first space 223. For example, a faster speed of rotation of the workpiece 301 during the dispensing of the sealant spots 370 will result in an increased distance between adjacent sealant spots 370 as shown in the region 371A of the workpiece 301 in FIG. 8B. Therefore the faster speed of rotation will result in a smaller volume of sealant being dispensed in the first space 223 along the perimeter of the bonding interface between the first wafer 10 and the second wafer 20. Conversely, a slower speed of rotation of the workpiece 301 during the dispensing of the sealant spots 370 will result in a reduced distance between adjacent sealant spots 370 as shown in the region 371B of the workpiece 301 in FIG. 8B. Therefore the slower speed of rotation will result in a greater volume of sealant being dispensed in the first space 223 along the perimeter of the bonding interface between the first wafer 10 and the second wafer 20. In this way, the volume of sealant dispensed into the first space 223 can be controlled by varying the speed of rotation of the workpiece 301 during the dispensing of the sealant.

After the step 312 of the process flow 300 is performed, a step 314 of the process flow 300 (shown in FIG. 5) is performed. In the step 314 of the process flow 300, a second inspection of the edges of the workpiece 301 is performed in the dispensing chamber 346 using a combination of the laser edge profiler 354 and the CCD camera 358. The laser edge profiler 354 and the CCD camera 358 are used to perform the second inspection in a similar manner as to how the laser edge profiler 354 and the CCD camera 358 were respectively used to perform the first inspection (described previously in step 308 of the process flow 300). The second inspection is used to determine the quality of the bevel seal 225 that was formed in the step 312 of the process flow 300. Referring to FIGS. 1 and 9A, each of the CCD camera 358 and the laser edge profiler 354 may be disposed to be adjacent to an edge of the workpiece 301. The CCD camera 358 is used to capture 2-dimensional (2D) images along the perimeter (e.g., edges) of the workpiece 301, including beveled edges of the first wafer 10 and the second wafer 20, as well as the bevel seal 225. The 2D images are captured by the CCD camera 358 as the workpiece 301 is rotated. The 2D images comprise variations in the intensity or brightness levels of objects or features within each 2D image, and these variations are typically represented in shades of gray. Grey-level contrast differences can be used to distinguish and analyze objects, patterns, or details in each 2D image, such as the position of the bevel seal 225 that is disposed between the beveled edges of the first wafer 10 and the second wafer 20. For example, FIG. 9B shows an example 2D image that may be captured by the CCD camera 358, the 2D image showing the bevel seal 225 that is disposed between the beveled edges of the first wafer 10 and the second wafer 20. The CCD camera 358 observes the bevel seal 225, the first wafer 10 and the second wafer 20 by detecting and capturing changes in light intensity on the bevel seal and at certain locations on each of the first wafer 10 and the second wafer 20. For example, horizontal lines in FIG. 9B represent a location 1 and a location 2 on the beveled edge of the second wafer 20 which are observable by the CCD camera 358 due to variations in light intensity at the location 1 and the location 2, as compared to the rest of the second wafer 20. In addition, horizontal lines in FIG. 9B represent a location 3 and a location 4 on the beveled edge of the first wafer 10 which are observable by the CCD camera 358 due to variations in light intensity at the location 3 and the location 4, as compared to the rest of the first wafer 10. Further, the bevel seal 225 is observable by the CCD camera 358 due to variations in light intensity on the material of the bevel seal 225 as compared to the materials of the first wafer 10 and the second wafer 20. In this way the CCD camera 358 is able to observe the dimensions of the bevel seal 225, and the bevel seal 225 can be examined to ensure it has a uniform width with no visible gaps, thereby ensuring the formation of a good quality bevel seal 225.

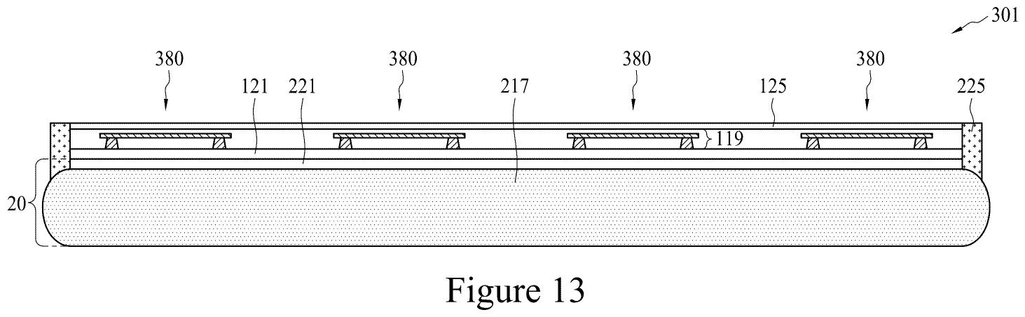

Further as seen in the 2D image of FIG. 9B, the CCD camera 358 can also observe if any sealant has splashed (e.g., in the form of sealant splashes 372) from out of the first space 223 and on to the beveled edges of the first wafer 10 and/or the second wafer 20. If one or more sealant splashes 372 are observed as a result of the second inspection, a subsequent cleaning process (described in detail in FIGS. 6 and 10) may be performed subsequently.

Referring further to FIGS. 1 and 9A, the laser edge profiler 354 collects data by measuring the profile (e.g. the shape and dimensions) of the beveled edges of the first wafer 10 and the second wafer 20 as the workpiece 301 is rotated. Therefore the laser edge profiler 354 collects data by measuring the profile (e.g. the shape and dimensions) of the edges of the workpiece 301. In addition, the laser edge profiler 354 measures the profile (e.g., the shape and dimensions) of the bevel seal 225 (shown previously in FIG. 4) between the lower beveled edge of the second wafer 20 and the upper beveled edge of the first wafer 10. This data is measured at various points along the perimeter of the workpiece 301 as the workpiece 301 is rotated.

The 2D images collected by the CCD camera 358 and the data measured by the laser edge profiler 354 during the second inspection are then sent to the data processor 348. The data processor 348 applies various algorithms to process the data, and reconstructs a 3-dimensional (3D) representation of the edges of the workpiece 301. For example, FIG. 9C shows a reconstructed 3D representation of a cross-section of the edge of the workpiece 301 that is shown in FIG. 9B. The 3D representation of the cross-section of the edge of the workpiece 301 shows the beveled edges of the first wafer 10 and the second wafer 20, as well as the dispensed sealant of the bevel seal 225 in the first space 223 between the lower beveled edge of the second wafer 20 and the upper beveled edge of the first wafer 10. The data processor 348 uses the 2D images collected by the CCD camera 358 and the reconstructed 3D representation of the edges of the workpiece 301 to determine the volume of sealant that has been dispensed into the first space 223 during the step 312 of the process flow 300 that forms the bevel seal 225. Therefore, the data processor 348 can determine if an adequate volume of the sealant has been dispensed during the step 312 of the process flow 300 to fill the first space 223 between the lower beveled edge of the second wafer 20 and the upper beveled edge of the first wafer 10. If the volume of the sealant that has been dispensed during the step 312 of the process flow 300 is found to be inadequate to fill the first space 223, a re-work process may be performed in the dispensing chamber 346 to dispense more sealant into the first space 223. The re-work process may be similar to the step 312 of the process flow 300 that was described above, and the re-work process ensures that the total volume of sealant of the bevel seal 225 is adequate, and therefore results in the formation of a good quality bevel seal 225.

Further, the data processor 348 can use the reconstructed 3D representation of the edges of the workpiece 301 (e.g., as shown in FIG. 9C) to detect if any sealant has splashed (e.g., in the form of sealant splashes 372) from out of the first space 223 and on to the beveled edges of the first wafer 10 and/or the second wafer 20. The data processor 348 can also use the reconstructed 3D representation of the edges of the workpiece 301 to detect if any sealant has splashed from out of the first space 223 and on to the top surface of the second wafer 20 or the bottom surface of the first wafer 10. If one or more sealant splashes 372 are detected as a result of the second inspection, a subsequent cleaning process (described in detail in FIGS. 6 and 10) may be performed subsequently.

Advantages can be achieved by performing the second inspection in the dispensing chamber 346 using a combination of the laser edge profiler 354 and the CCD camera 358, wherein the CCD camera 358 is used to capture 2D images along the edges of the workpiece 301, including the bevel seal 225, as the workpiece 301 is rotated. The laser edge profiler 354 collects data by measuring the profile (e.g. the shape and dimensions) of the edges of the workpiece 301, including the bevel seal 225, as the workpiece 301 is rotated. The 2D images collected by the CCD camera 358 and the data measured by the laser edge profiler 354 during the second inspection are sent to the data processor 348, which the data processor 348 uses to reconstruct a 3D representation of the edges of the workpiece 301, including the bevel seal 225. These advantages include the data processor 348 being able to use the 2D images collected by the CCD camera 358 and the reconstructed 3D representation of the edges of the workpiece 301 to determine the quality of the bevel seal 225 formed in the step 312 of the process flow 300. The CCD camera 358 is able to observe the dimensions of the bevel seal 225, and the bevel seal 225 can be examined to ensure it has a uniform width with no visible gaps, thereby ensuring the formation of a good quality bevel seal 225. In addition, the data processor 348 can use the 2D images collected by the CCD camera 358 and the reconstructed 3D representation of the edges of the workpiece 301 to determine if any sealant has splashed (e.g., in the form of sealant splashes 372) from out of the first space 223 and on to the beveled edges of the first wafer 10 and/or the second wafer 20, and if a subsequent cleaning process is required to remove the splashed sealant. The data processor 348 can also use the 2D images collected by the CCD camera 358 and the reconstructed 3D representation of the edges of the workpiece 301, including the bevel seal 225, to determine if an adequate volume of the sealant to fill the first space 223 has been dispensed during the step 312 of the process flow 300 in order to form the bevel seal 225. Hence, the data processor 348 can therefore determine if a subsequent re-work process needs to be performed to dispense more sealant in the first space 223, if the volume of the sealant of the bevel seal 225 is found to be inadequate. As a result, a high quality bevel seal 225 can be formed that allows for improved device reliability and reduced manufacturing costs. In addition, the resulting bevel seal 225 that is formed is highly resistant to a subsequent thinning process 380 (described subsequently in FIG. 13) that is used to remove or reduce a thickness of the first wafer 10. As a result, the edges of the workpiece 301 are strengthened due to the formation of the high quality bevel seal 225, which allows for a reduced amount of peeling of the materials of the first wafer 10 and the second wafer 20 at the edges of the bonding interface during the thinning process 380.

After the step 314 of the process flow 300 is performed, a step 316 of the process flow 300 (shown in FIG. 5) is performed. In the step 316 of the process flow 300, the workpiece 301 is transferred using the transfer robot to the wafer transfer station 344 of the bevel sealing system 340 (shown in FIG. 1). In step 318 of the process flow 300 (shown in FIG. 5), the transfer robot then transfers the workpiece 301 from the wafer transfer station 344 to one of the load ports 342 of the bevel sealing system 340, from where the workpiece 301 is removed from the bevel sealing system 340.

FIG. 6 schematically illustrates a process flow 320 and the bevel sealing system 340 for performing the process flow 320. The bevel sealing system 340 and the process flow 320 may be used to perform a cleaning process on the workpiece 301, if during the second inspection (described previously in the step 314 of the process flow 300), one or more sealant splashes 372 are detected on the beveled edges of the first wafer 10 and/or the second wafer 20. The cleaning process can also be performed on the workpiece 301 if during the second inspection, one or more sealant splashes 372 are detected on the top surface of the second wafer 20 and/or the bottom surface of the first wafer 10. The details of the process flow 320 and the bevel sealing system 340 are discussed below, referencing FIGS. 1, 6, and 10 through 11B.

In step 322 of the process flow 320 (shown in FIG. 6), the workpiece 301 is delivered to one of the load ports 342 of the bevel sealing system 340. In step 324 of the process flow 320 (shown in FIG. 6), a transfer robot is used to transfer the workpiece 301 from the load port 342 to the wafer transfer station 344, where the workpiece 301 can be staged for transfer to any other chamber of the bevel sealing system 340.

In step 326 of the process flow 320 (shown in FIG. 6), the transfer robot transfers the workpiece 301 from the wafer transfer station 344 to the cleaning chamber 350. In addition, in the cleaning chamber 350, a third inspection of the edges of the workpiece 301 is performed using the laser edge profiler 362, and the CCD camera 364. The laser edge profiler 362 and the CCD camera 364 are used to perform the third inspection in a similar manner as to how the laser edge profiler 354 and the CCD camera 358 were used, respectively, to perform the second inspection (described previously in step 314 of the process flow 300). The 2D images collected by the CCD camera 364 and the data measured by the laser edge profiler 362 during the third inspection are then sent to the data processor 348. The data processor 348 uses the 2D images collected by the CCD camera 364 and the reconstructed 3D representation of the edges of the workpiece 301 to confirm the positions of the one or more sealant splashes 372 that were detected previously during the second inspection (described previously in step 314 of the process flow 300). The one or more sealant splashes 372 may be disposed on the beveled edges of the first wafer 10 and/or the second wafer 20, or on the top surface of the second wafer 20 and/or the bottom surface of the first wafer 10.

After the step 326 of the process flow 320 is performed, a step 328 of the process flow 320 (shown in FIG. 6) is performed. In the step 328 of the process flow 320 (shown in FIG. 6), the cleaning apparatus 360 (described previously in FIG. 1) is used to perform a cleaning process on the workpiece 301 to remove and wipe out the one or more sealant splashes 372 on the beveled edges of the first wafer 10 and the second wafer 20, or on the top surface of the second wafer 20 and/or the bottom surface of the first wafer 10. Referring to FIG. 10, the cleaning apparatus 360 may comprise on one or more cleaning brushes (e.g., a top/bottom cleaning brush 376 and a side cleaning brush 374) that are rotatable and that may be brought into contact with the beveled edges and/or a top bottom surface of the workpiece 301. For example, one or more rotatable side cleaning brushes 374 can be brought into contact with the beveled edges of the first wafer 10 and/or the second wafer 20 to remove and wipe out the one or more sealant splashes 372 on the beveled edges of the first wafer 10 and the second wafer 20. In addition, one or more rotatable top/bottom cleaning brushes 376 can be brought into contact with the top surface of the second wafer 20 or the bottom surface of the first wafer 10 to remove and wipe out the one or more sealant splashes 372 on the bottom surface of the first wafer 10 and/or the top surface of the second wafer 20.

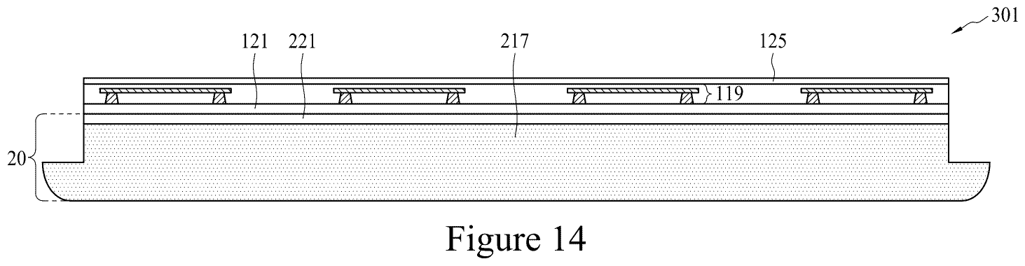

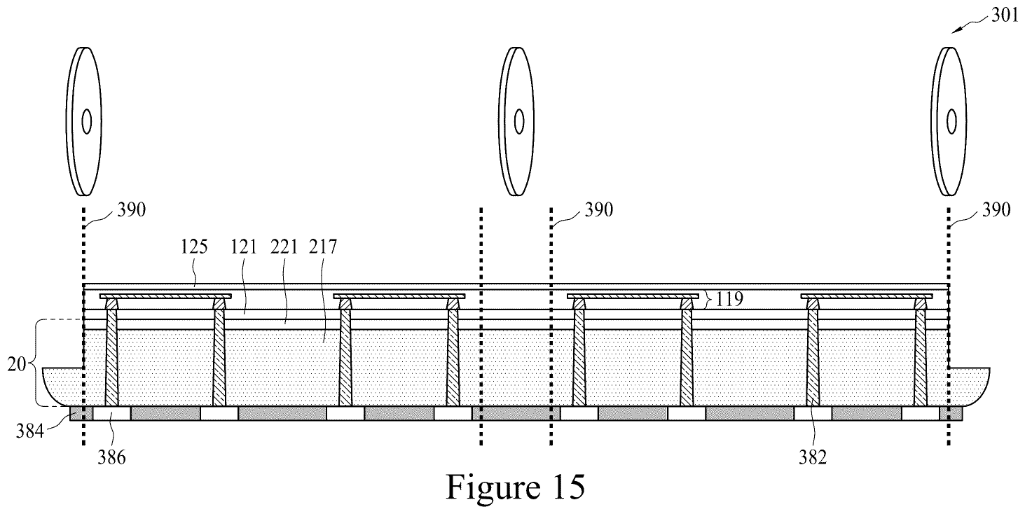

After the step 328 of the process flow 320 is performed, a step 330 of the process flow 320 (shown in FIG. 6) is performed. In the step 330 of the process flow 320, a fourth inspection is performed on the edges of the workpiece 301 using the laser edge profiler 362, and the CCD camera 364. The laser edge profiler 362 and the CCD camera 364 are used to perform the fourth inspection in a similar manner as to how the laser edge profiler 354 and the CCD camera 358, respectively, were used to perform the second inspection (described previously in step 314 of the process flow 300). The 2D images collected by the CCD camera 364 and the data measured by the laser edge profiler 362 during the fourth inspection are then sent to the data processor 348. The data processor 348 reconstructs a 3-dimensional (3D) representation of the edges of the workpiece 301. For example, FIG. 11A shows an example 2D image that may be captured by the CCD camera 364 during the fourth inspection, and FIG. 11B shows a reconstructed 3D representation of a cross-section of the edge of the workpiece 301 that is shown in FIG. 11A. The data processor 348 compares the 2D images collected by the CCD camera 364 and the reconstructed 3D representation of the edges of the workpiece 301 obtained during the fourth inspection to the respective 2D images collected by the CCD camera 364 and the reconstructed 3D representation of the edges of the workpiece 301 obtained during the third inspection, to determine if the one or more sealant splashes 372 have been completely removed from the beveled edges of the first wafer 10 and the second wafer 20, or from the bottom surface of the first wafer 10 and/or the top surface of the second wafer 20.

In addition, the CCD camera 364 observes the bevel seal 225, the first wafer 10 and the second wafer 20 by detecting and capturing changes in light intensity on the bevel seal and at certain locations on each of the first wafer 10 and the second wafer 20. The bevel seal 225 is observable by the CCD camera 364 (e.g., as shown in FIG. 11A) due to variations in light intensity on the material of the bevel seal 225 as compared to the materials of the first wafer 10 and the second wafer 20. In this way the CCD camera 364 is able to observe the dimensions of the bevel seal 225, and the bevel seal 225 can be examined to ensure it has a uniform width with no visible gaps, thereby ensuring the formation of a good quality bevel seal 225.

Further, the data processor 348 uses the 2D images collected by the CCD camera 364 and the reconstructed 3D representation (as shown in FIG. 11B) of the edges of the workpiece 301 to determine the volume of sealant that remains in the first space 223 and which forms the bevel seal 225. Therefore, the data processor 348 can determine the volume of the sealant that has been removed from the first space 223 during the cleaning process described above in the step 328 of the process flow 320. The data processor 348 determines the volume of the removed sealant by comparing the reconstructed 3D representation of the edges of the workpiece 301 obtained during the fourth inspection to the reconstructed 3D representation of the edges of the workpiece 301 obtained during the third inspection (described previously in the step 326 of the process flow 320). If after the fourth inspection the volume of the sealant that forms the bevel seal 225 is found to be inadequate, a re-work process may be performed subsequently in the dispensing chamber 346 to dispense more sealant into the first space 223. The re-work process may be similar to the step 312 of the process flow 300 (shown in FIG. 5) that was described above, and the re-work process ensures that the total volume of sealant of the bevel seal 225 is adequate, and therefore results in the formation of a good quality bevel seal 225.

Advantages can be achieved by performing the fourth inspection in the cleaning chamber 350, after the cleaning process (described in the step 328 of the process flow 320) is performed on the workpiece 301. The fourth inspection is performed using a combination of the laser edge profiler 362 and the CCD camera 364, wherein the CCD camera 364 is used to capture 2D images along the edges of the workpiece 301, including the bevel seal 225, as the workpiece 301 is rotated. The laser edge profiler 362 collects data by measuring the profile (e.g. the shape and dimensions) of the edges of the workpiece 301, including the bevel seal 225, as the workpiece 301 is rotated. The 2D images collected by the CCD camera 364 and the data measured by the laser edge profiler 362 during the fourth inspection are sent to the data processor 348, which the data processor 348 uses to reconstruct a 3D representation of the edges of the workpiece 301, including the bevel seal 225. These advantages include the data processor 348 being able to compare the 2D images collected by the CCD camera 364 and the reconstructed 3D representation of the edges of the workpiece 301 obtained during the fourth inspection to the respective 2D images collected by the CCD camera 364 and the reconstructed 3D representation of the edges of the workpiece 301 obtained during the third inspection. In this way the data processor 348 can determine if the one or more sealant splashes 372 have been completely removed from the beveled edges of the first wafer 10 and the second wafer 20, or from the bottom surface of the first wafer 10 and/or the top surface of the second wafer 20 as a result of the cleaning process (described in the step 328 of the process flow 320). In addition, the data processor 348 can use the 2D images collected by the CCD camera 364 and the reconstructed 3D representation of the edges of the workpiece 301 to determine the quality of the bevel seal 225. The CCD camera 364 is able to observe the dimensions of the bevel seal 225, and the bevel seal 225 can be examined to ensure it has a uniform width with no visible gaps, thereby ensuring the formation of a good quality bevel seal 225. In addition, the data processor 348 determines the volume of the sealant that was removed during the cleaning process (described in the step 328 of the process flow 320) by comparing the reconstructed 3D representation of the edges of the workpiece 301 obtained during the fourth inspection to the reconstructed 3D representation of the edges of the workpiece 301 obtained during the third inspection. If as a result of the fourth inspection the volume of the remaining sealant that forms the bevel seal 225 is found to be inadequate, a re-work process may be performed subsequently in the dispensing chamber 346 to dispense more sealant into the first space 223. The re-work process ensures that the total volume of sealant of the bevel seal 225 is adequate, and therefore results in the formation of a good quality bevel seal 225.

After the step 330 of the process flow 320 is performed, a step 332 of the process flow 320 (shown in FIG. 6) is performed. In the step 332 of the process flow 320, the workpiece 301 is transferred using the transfer robot to the wafer transfer station 344 of the bevel sealing system 340 (shown in FIG. 1). In step 334 of the process flow 320 (shown in FIG. 6), the transfer robot then transfers the workpiece 301 from the wafer transfer station 344 to one of the load ports 342 of the bevel sealing system 340, from where the workpiece 301 is removed from the bevel sealing system 340.

FIG. 12 illustrates the workpiece 301 after the step 318 of the process flow 300 (shown in FIG. 5) is performed, or after the step 334 of the process flow 320 (shown in FIG. 6) is performed, in which the transfer robot transfers the workpiece 301 from the wafer transfer station 344 to one of the load ports 342 of the bevel sealing system 340. The workpiece 301 is then removed from the bevel sealing system 340. In FIG. 12, a curing process is performed to convert the sealant (e.g., an epoxy) of the bevel seal 225 from a liquid or semi-liquid state to a solid, durable, and chemically stable state. After the curing process is performed, the bevel seal 225 becomes harder and more resistant to deformation. The curing process may comprise heating the workpiece 301 to a temperature that is in a range from 150° C. to 220° C. After the curing process is performed, the workpiece 301 is flipped over such that the first wafer 10 is disposed over the second wafer 20.

In FIG. 13, a thinning process 380 is performed on the back side of the first wafer 10, such as on the exposed surface of the substrate 117. The thinning process 380 removes the substrate 117 of the first wafer 10, such that the device layer 125 remains disposed on the second wafer 20. The thinning process 380 may include planarizing the surface of the substrate 117 using CMP, grinding, etching (e.g., a wet etch or a dry etch process), a combination thereof, or the like. For example, the thinning process 380 may be performed in a grinding machine, where a rotating abrasive wheel is used to remove the material of the substrate 117. In an embodiment, portions of the bevel seal 225 on a beveled edge of the first wafer 10 may also be removed during the thinning process 380. In an embodiment, after the thinning process 380, a top surface of the device layer 125 and a top surface of the bevel seal 225 may be at the same level. Advantages can be achieved by using the process flow 300 to form the bevel seal 225 along the perimeter of the bonding interface between the first wafer 10 and the second wafer 20. These advantages include the resulting bevel seal 225 being highly resistant to the thinning process 380 that is used to reduce a thickness of the first wafer 10. As a result, the edges of the workpiece 301 are strengthened due to the formation of the high quality bevel seal 225, which allows for a reduced amount of peeling of the materials of the first wafer 10 and the second wafer 20 at the edges of the bonding interface during the thinning process 380. As a consequence, device reliability is improved and manufacturing costs are greatly reduced.

In FIG. 14, a trimming process is performed on the workpiece 301 to remove edge portions of the workpiece 301. For example, the trimming process may partially remove edge portions of the semiconductor substrate 217 that are on the perimeter of the workpiece 301. In addition, the trimming process may remove edge portions of the bonding layer 221, the bonding layer 121, the interconnect structure 119, and the device layer 125 that are on the perimeter of the workpiece 301. The trimming process may comprise a laser trimming process, a blade trimming process, or the like. In an embodiment, the trimming process may comprise forming a patterned mask (e.g., a patterned photoresist) over the workpiece 301. An etching process may then be performed to remove the edge portions of the workpiece 301 (e.g., portions of the semiconductor substrate 217, the bonding layer 221, the bonding layer 121, the interconnect structure 119, and the device layer 125) that are not protected by the patterned mask. The protected regions (under the mask) are not affected. The patterned mask may then be removed by an acceptable ashing or stripping process.

In FIG. 15, through substrate vias (TSVs) 382 are formed that extend through the semiconductor substrate 217, the bonding layer 121, and the bonding layer 221. The TSVs 382 may also extend partially through the interconnect structure 119. TSVs 382 may be electrically connected to the metallization patterns in the interconnect structure 119, as well as to the active and/or passive devices of the device layer 125. The TSVs 382 may be formed by, for example, flipping the workpiece 301 and forming openings on a first side (e.g. on an exposed surface) of the semiconductor substrate 217 by, for example, etching, milling, laser techniques, a combination thereof, and/or the like. The openings may extend through the semiconductor substrate 217, the bonding layer 121, and the bonding layer 221. The openings may expose metallization patterns in the interconnect structure 119. A thin barrier layer may be conformally deposited over the first side of the semiconductor substrate 217 and in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the first side of the semiconductor substrate 217 by, for example, chemical mechanical polishing. Thus, in some embodiments, the TSVs 382 may comprise a conductive material and a thin barrier layer between the conductive material and the semiconductor substrate 217. The TSVs 382 provide electrical connection from the first side of the semiconductor substrate 217 to a second side of the semiconductor substrate 217, wherein the second side is on an opposite side of the semiconductor substrate 217 as the first side.

Referring further to FIG. 15, a dielectric layer 384 is formed on the first side of the semiconductor substrate 217 and on the exposed surfaces of the TSVs 382. The dielectric layer 384 may comprise silicon oxide, silicon nitride, silicon carbide, silicon oxynitride, low-K dielectric material, such as phosphosilicate glass (PSG), borophosphosilicate glass (BPSG), fluorosilicate glass (FSG), SiOₓCy, Spin-On-Glass, Spin-On-Polymers, silicon carbon material, compounds thereof, composites thereof, combinations thereof, or the like. The dielectric layer 384 may be deposited by any suitable method, such as, CVD, PECVD, spinning, or the like.

Metallization patterns 386 may be formed in the dielectric layer 384, for example, by using photolithography techniques to deposit and pattern a photoresist material on the dielectric layer 384 to expose portions of the dielectric layer 384 that are to become the metallization patterns 386. An etch process, such as an anisotropic dry etch process, may be used to create openings in the dielectric layer 384 corresponding to the exposed portions of the dielectric layer 384. The openings in the dielectric layer 384 may expose the TSVs 382. A seed layer (not separately illustrated) is formed over the exposed surfaces of the dielectric layer 384 and in the openings in the dielectric layer 384. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization patterns 386. The patterning forms openings through the photoresist to expose the seed layer. A conductive material is then formed in the openings and on the exposed portions of the seed layer. The conductive material may be formed by plating, such as electroplating, electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material in the dielectric layer 384 form the metallization patterns 386. These metallization patterns 386 will be used to electrically connect the TSVs 382, the interconnect structure 119, and the device layer 125 to external devices. In some embodiments, power is delivered to the device layer 125 using the metallization patterns 386. In some embodiments, the metallization patterns 386 may also include under Bump Metallizations (UBMs) to which conductive connectors (not shown in the Figures) may be attached for attachment and electrical connection to external devices or a power supply.

In FIG. 16, a singulation process is performed on the workpiece 301 to singulate individual semiconductor devices 400 of the workpiece 301 from one another. The semiconductor devices 400 may also be referred to as semiconductor dies. The singulation process may include a mechanical process such as a sawing process, a cutting process, or the like. In some embodiments, the singulation process may include a lasering process, mechanical process, and/or combinations thereof. The singulation is performed along the scribe line regions 390 (shown in FIG. 15) through the device layer 125, the interconnect structure 119, the bonding layer 121, the bonding layer 221, the semiconductor substrate 217, and the dielectric layer 384.

The embodiments of the present disclosure have some advantageous features. The embodiments provide methods applied to the use of a bevel sealing system in order to form a bevel seal along a perimeter of the bonding interface between a first wafer and a second wafer (e.g., that form a workpiece). The bevel seal is formed by dispensing a sealant in a first space between a beveled edge of the first wafer and a beveled edge of the second wafer. The bevel sealing system comprises a laser edge profiler and a Charge-Coupled Device (CCD) camera, which are used to perform a first inspection of the perimeter of the workpiece, including the beveled edges of the bonded first wafer and the second wafer, as well as the bonding interface between the first wafer and the second wafer. The first inspection is performed prior to forming the bevel seal, and the first inspection allows the bevel sealing system to determine an optimal dispensing path and height along the perimeter of the workpiece in which to apply the sealant. In addition, the first inspection can be used to determine the volume of sealant that is needed to be dispensed in order to adequately fill the first space between the beveled edge of the first wafer and the beveled edge of the second wafer. A second inspection using the laser edge profiler and the CCD camera is performed after the bevel seal is formed to determine the quality of the bevel seal formed. The second inspection can determine if an adequate volume of sealant needed to fill the first space has been dispensed, or if portions of the sealant have splashed out of the first space and onto other surfaces of the beveled edges of the first wafer and/or the second wafer. Therefore, the second inspection can determine if a cleaning process needs to be performed to clean the splashed sealant from the surfaces of the beveled edges of the first wafer and/or the second wafer. It can also determine if a further re-work process needs to be performed to dispense more sealant in the first space if the volume of the sealant is inadequate. As a result, a high quality bevel seal can be formed that allows for improved device reliability and reduced manufacturing costs. In addition, the resulting bevel seal that is formed is highly resistant to subsequent thinning operations that are used to remove or reduce a thickness of the first wafer or the second wafer. As a result, the edges of the workpiece are strengthened due to the formation of the high quality bevel seal, which allows for a reduced amount of peeling of the materials of the first wafer and the second wafer at the edges of the bonding interface during the thinning operations. Further, the use of the first inspection and/or the second inspection allows for detection of defects (e.g., edge defects on the first wafer and/or the second wafer) and bonding misalignments between the first wafer and the second wafer.

In accordance with an embodiment, a bevel sealing system includes a dispensing chamber including a first chuck configured to support a workpiece, the workpiece including a first wafer bonded to a second wafer, where the first wafer and the second wafer include beveled edges; a sealant dispenser configured to apply sealant along a perimeter of a bonding interface between the first wafer and the second wafer; a first Charge-Coupled Device (CCD) camera configured to capture 2-dimensional (2D) images of edges of the workpiece; and a first laser edge profiler configured to measure and collect profile data of the edges of the workpiece. In an embodiment, the bevel sealing system further includes a data processor configured to reconstruct a 3-dimensional (3D) representation of the edges of the workpiece using the 2D images of the edges of the workpiece and the profile data of the edges of the workpiece. In an embodiment, the bevel sealing system further includes a cleaning chamber including a second chuck configured to support the workpiece; a second CCD camera configured to capture 2D images of the edges of the workpiece; and a second laser edge profiler configured to measure and collect profile data of the edges of the workpiece. In an embodiment, the cleaning chamber further includes one or more cleaning brushes configured to come into contact with the edges of the workpiece. In an embodiment, the sealant dispenser is also configured to apply the sealant in a first space between a first beveled edge of the first wafer and a second beveled edge of the second wafer.

In accordance with an embodiment, a method of forming a bevel seal includes bonding a front side of a device wafer to a carrier wafer to form a workpiece, where a first space is disposed between a first beveled edge of the device wafer and a second beveled edge of the carrier wafer, the first space also extending along a perimeter of a bonding interface between the device wafer and the carrier wafer; performing a first inspection of edges of the workpiece, where the first inspection includes capturing a first set of 2-dimensional (2D) images of the edges of the workpiece using a first Charge-Coupled Device (CCD) camera; and measuring and collecting a first set of profile data of the edges of the workpiece using a first laser edge profiler; and reconstructing a first 3-dimensional (3D) representation of the edges of the workpiece using the first set of 2D images of the edges of the workpiece and the first set of profile data of the edges of the workpiece. In an embodiment, reconstructing the first 3D representation of the edges of the workpiece includes using a data processor to process the first set of profile data of the edges of the workpiece. In an embodiment, the method further includes dispensing a sealant into the first space that extends along the perimeter of the bonding interface between the device wafer and the carrier wafer. In an embodiment, the method further includes prior to dispensing the sealant into the first space, determining an optimal dispensing path and height in the first space along which to dispense the sealant, where the optimal dispensing path and height in the first space is determined using the first set of 2D images of the edges of the workpiece and the first 3D representation of the edges of the workpiece. In an embodiment, the method further includes prior to dispensing the sealant into the first space, determining a volume of the sealant to be dispensed into the first space in order to fill the first space, where the volume of the sealant to be dispensed into the first space is determined using the first 3D representation of the edges of the workpiece. In an embodiment, the method further includes after dispensing the sealant into the first space, performing a thinning process to remove a substrate of the device wafer, where during the thinning process, portions of the sealant in the first space are also removed. In an embodiment, the method further includes after dispensing the sealant into the first space, performing a second inspection of the edges of the workpiece, where the second inspection includes capturing a second set of 2D images of the edges of the workpiece using the first CCD camera; and measuring and collecting a second set of profile data of the edges of the workpiece using the first laser edge profiler. In an embodiment, the method further includes reconstructing a second 3D representation of the edges of the workpiece using the second set of 2D images of the edges of the workpiece and the second set of profile data of the edges of the workpiece. In an embodiment, the method further includes determining a volume of the sealant that has been dispensed into the first space, where the volume of the sealant dispensed into the first space is determined using the second set of 2D images of the edges of the workpiece and the second 3D representation of the edges of the workpiece.

In accordance with an embodiment, a method includes bonding an interconnect structure of a first wafer to a second wafer to form a wafer stack, where a first space is disposed between a lower beveled edge of the second wafer and an upper beveled edge of the first wafer, the first space extending along a perimeter of a bonding interface between the first wafer and the second wafer; forming a bevel seal in the first space along the perimeter of the bonding interface between the first wafer and the second wafer, where forming the bevel seal includes measuring and collecting a first set of profile data of edges of the wafer stack using a first laser edge profiler; and reconstructing a first 3-dimensional (3D) representation of the edges of the wafer stack using the first set of profile data of the edges of the wafer stack; determining a volume of sealant to be dispensed into the first space in order to fill the first space, where the volume of the sealant to be dispensed into the first space is determined using the first 3D representation of the edges of the wafer stack; and dispensing the sealant into the first space that extends along the perimeter of the bonding interface between the first wafer and the second wafer. In an embodiment, the method further includes capturing a first set of 2-dimensional (2D) images of the edges of the wafer stack using a first Charge-Coupled Device (CCD) camera. In an embodiment, the method further includes after dispensing the sealant into the first space, capturing a second set of 2D images of the edges of the wafer stack using the first CCD camera; and after dispensing the sealant into the first space, measuring and collecting a second set of profile data of the edges of the wafer stack using the first laser edge profiler. In an embodiment, the method further includes reconstructing a second 3D representation of the edges of the wafer stack using the second set of profile data of the edges of the wafer stack. In an embodiment, the method further includes determining whether to perform a cleaning process on the edges of the wafer stack based on the second set of 2D images of the edges of the wafer stack and the second 3D representation of the edges of the wafer stack. In an embodiment, the method further includes performing the cleaning process on the edges of the wafer stack; after performing the cleaning process on the edges of the wafer stack, capturing a third set of 2D images of the edges of the wafer stack using a second CCD camera; and after performing the cleaning process on the edges of the wafer stack, measuring and collecting a third set of profile data of the edges of the wafer stack using a second laser edge profiler.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a workpiece by bonding a device wafer to a carrier wafer, wherein a first space extends along a perimeter of a bonding interface between the device wafer and the carrier wafer, wherein the first space is disposed between a first beveled edge of the device wafer and a second beveled edge of the carrier wafer;
determining a volume of sealant to be dispensed into the first space in order to fill the first space, wherein the volume of the sealant to be dispensed into the first space is determined using a first 3-dimensional (3D) representation of edges of the workpiece; and
dispensing a sealant into the first space that extends along the perimeter of the bonding interface between the device wafer and the carrier wafer.

2. The method of claim 1, wherein determining the volume of the sealant to be dispensed into the first space comprises:
capturing a first set of 2-dimensional (2D) images of the edges of the workpiece using a first Charge-Coupled Device (CCD) camera.

3. The method of claim 2, wherein determining the volume of the sealant to be dispensed into the first space further comprises:
measuring and collecting a first set of profile data of the edges of the workpiece using a first laser edge profiler.

4. The method of claim 3, further comprising:
rotating the workpiece during capturing the first set of 2D images of the edges of the workpiece, and during measuring and collecting the first set of profile data of the edges of the workpiece.

5. The method of claim 3, wherein determining the volume of the sealant to be dispensed into the first space further comprises:
reconstructing the first 3D representation of the edges of the workpiece using the first set of 2D images of the edges of the workpiece and the first set of profile data of the edges of the workpiece.

6. The method of claim 5, wherein determining the volume of the sealant to be dispensed into the first space further comprises:
determining an optimal dispensing path and height in the first space along which to dispense the sealant, wherein the optimal dispensing path and height in the first space is determined using the first set of 2D images of the edges of the workpiece and the first 3D representation of the edges of the workpiece.

7. The method of claim 5, wherein reconstructing the first 3D representation of the edges of the workpiece comprises using a data processor to process the first set of profile data of the edges of the workpiece.

8. The method of claim 1, wherein dispensing the sealant into the first space comprises:
applying the sealant in the first space between the first beveled edge of the device wafer and the second beveled edge of the carrier wafer using a sealant dispenser.

9. A method of forming a bevel seal, the method comprising:
bonding a first wafer to a second wafer to form a workpiece, a first space being disposed between a first beveled edge of the first wafer and a second beveled edge of the second wafer, the first space also extending along a perimeter of a bonding interface between the first wafer and the second wafer;
rotating the workpiece;
during rotating the workpiece, capturing a first set of 2-dimensional (2D) images of edges of the workpiece using a first Charge-Coupled Device (CCD) camera; and
during rotating the workpiece, collecting a first set of profile data of the edges of the workpiece using a first laser edge profiler.

10. The method of claim 9, further comprising:
reconstructing a first 3-dimensional (3D) representation of the edges of the workpiece using the first set of 2D images of the edges of the workpiece and the first set of profile data of the edges of the workpiece.

11. The method of claim 10, further comprising:
dispensing a sealant into the first space that extends along the perimeter of the bonding interface between the first wafer and the second wafer.

12. The method of claim 11, further comprising:
prior to dispensing the sealant into the first space, determining an optimal dispensing path and height in the first space along which to dispense the sealant, wherein the optimal dispensing path and height in the first space is determined using the first set of 2D images of the edges of the workpiece and the first 3D representation of the edges of the workpiece.

13. The method of claim 11, further comprising:
prior to dispensing the sealant into the first space, determining a volume of the sealant to be dispensed into the first space in order to fill the first space, wherein the volume of the sealant to be dispensed into the first space is determined using the first 3D representation of the edges of the workpiece.

14. The method of claim 11, wherein collecting the first set of profile data of the edges of the workpiece using the first laser edge profiler comprises illuminating the edges of the workpiece using a laser light from the first laser edge profiler.

15. A bevel sealing system comprising:
a dispensing chamber comprising:
a first chuck configured to support a workpiece using a first vacuum, the workpiece comprising a first wafer bonded to a second wafer, wherein the first wafer and the second wafer comprise beveled edges;
a first Charge-Coupled Device (CCD) camera configured to capture 2-dimensional (2D) images of edges of the workpiece; and
a first laser edge profiler configured to measure and collect profile data of the edges of the workpiece; and
a cleaning chamber comprising:
a second chuck configured to support the workpiece using a second vacuum;
a second CCD camera configured to capture 2D images of the edges of the workpiece; and
a second laser edge profiler configured to measure and collect profile data of the edges of the workpiece.

16. The bevel sealing system of claim 15, further comprising a sealant dispenser configured to apply sealant along a perimeter of a bonding interface between the first wafer and the second wafer.

17. The bevel sealing system of claim 15, further comprising a data processor configured to reconstruct a first 3-dimensional (3D) representation of the edges of the workpiece using the 2D images of the edges of the workpiece captured by the first CCD camera and the profile data of the edges of the workpiece captured by the first laser edge profiler.

18. The bevel sealing system of claim 17, wherein the data processor is also configured to reconstruct a second 3D representation of the edges of the workpiece using the 2D images of the edges of the workpiece captured by the second CCD camera and the profile data of the edges of the workpiece captured by the second laser edge profiler.

19. The bevel sealing system of claim 15, wherein the first chuck and the second chuck are configured to be rotatable.

20. The bevel sealing system of claim 15, wherein the cleaning chamber further comprises one or more cleaning brushes configured to come into contact with the edges of the workpiece.
